(19) United States
(12) Patent Application Publication
(10) Pub. No.: US 2021/0399304 A1
(43) Pub. Date: Dec. 23, 2021

(54) NEGATIVE ACTIVE MATERIAL FOR RECHARGEABLE LITHIUM BATTERY, METHOD OF PREPARING SAME, AND RECHARGEABLE LITHIUM BATTERY INCLUDING THE SAME

(71) Applicant: Samsung SDI Co., Ltd., Yongin-si (KR)

(72) Inventors: Jungho LEE, Yongin-si (KR); Jaehou NAH, Yongin-si (KR); Hyun SOH, Yongin-si (KR); Inhyuk SON, Yongin-si (KR); Duk-Hyoung YOON, Yongin-si (KR)

(21) Appl. No.: 17/350,993

(22) Filed: Jun. 17, 2021

(30) Foreign Application Priority Data
Jun. 18, 2020 (KR) 10-2020-0074396

(51) Int. Cl. H01M 4/60; H01M 4/587; H01M 4/38; H01M 4/36; H01M 4/133; H01M 4/136; H01M 10/0525

(52) U.S. Cl. CPC H01M 4/60; H01M 4/587; H01M 4/386; H01M 4/366; H01M 2004/027; H01M 4/133; H01M 4/136; H01M 10/0525; H01M 4/364

(57) ABSTRACT

A negative active material for a rechargeable lithium battery includes an amorphous carbon matrix, silicon particles dispersed in the amorphous carbon matrix, and a nitrogen-containing carbon compound protruding outward from the surface of the amorphous carbon matrix. Additional embodiments provide a method of preparing the same and a rechargeable lithium battery including the same.

### CROSS-REFERENCE TO RELATED APPLICATION

This application claims priority to and the benefit of Korean Patent Application No. 10-2020-0074396 filed in the Korean Intellectual Property Office on Jun. 18, 2020, the entire content of which is incorporated herein by reference.

### BACKGROUND

### 1. Field

One or more aspects of embodiments of the present disclosure relate to a negative active material for a rechargeable lithium battery, a method of preparing the same, and a rechargeable lithium battery including the same.

### 2. Description of the Related Art

Technology for realizing rechargeable lithium batteries with high capacity is being continuously developed due to increasing demands of mobile equipment and/or portable batteries.

A lithium-transition metal oxide having a structure capable of intercalating lithium ions (such as LiCoO₂, LiMn₂O₄, LiNi₁₋ₓCoₓO₂ (0<x<1), and/or the like) has been utilized as a positive active material for a rechargeable lithium battery.

Various carbon-based materials, including artificial graphite, natural graphite, and hard carbon, which are capable of intercalating and deintercalating lithium ions, and silicon (Si)-based active materials including Si and/or tin (Sn) have been utilized as a negative active material for a rechargeable lithium battery.

### SUMMARY

One or more aspects of embodiments of the present disclosure are directed toward a negative active material for a rechargeable lithium battery having excellent or suitable charge and discharge characteristics and/or excellent or suitable cycle-life characteristics.

One or more aspects of embodiments of the present disclosure are directed toward a method of preparing the negative active material.

One or more aspects of embodiments of the present disclosure are directed toward a rechargeable lithium battery including the negative active material.

One or more embodiments of the present disclosure provide a negative active material for a rechargeable lithium battery, the negative active material including: an amorphous carbon matrix; silicon particles dispersed in the amorphous carbon matrix; and a nitrogen-containing carbon compound protruding outward from the surface of the amorphous carbon matrix.

The nitrogen-containing carbon compound may have an urchins-type (e.g., sea urchin-like) shape or structure on the surface of the amorphous carbon matrix.

The nitrogen-containing carbon compound may be semi-crystalline.

The nitrogen-containing carbon compound may include piperideine (C₅H₉N), piperidine (C₅H₁₁N), pyridine (C₅H₅N), pyrrole (C₄H₅N), aniline (C₆H₅NH₂), acetonitrile (C₂H₃N), dopamine (C₈H₁₁NO₂), dimethylamine, trimethylamine, ethylamine, diethylamine, trimethylamine, or a combination thereof.

A weight ratio of the amorphous carbon matrix and the nitrogen-containing carbon compound may be about 1:1 to about 1:2.

An amount of the silicon particles may be about 40 wt % to about 80 wt % based on the total weight (100 wt %) of the negative active material.

A particle diameter of the silicon particles may be about 40 nm to about 250 nm.

One or more embodiments of the present disclosure provide a method of preparing a negative active material for a rechargeable lithium battery, the method including: injecting a first carbon gas into silicon particles and performing heat treatment to prepare an amorphous carbon matrix in which the silicon particles are dispersed; and performing a deposition process utilizing a second carbon gas and a gas of a nitrogen-containing compound to form a nitrogen-containing carbon compound protruding outward from the surface of the amorphous carbon matrix.

The injecting of the first carbon gas may be performed at a temperature of about 600° C. to about 800° C.

The deposition process may be a chemical vapor deposition (CVD) process. The deposition process may be performed at a temperature of greater than or equal to about 1000° C.

The first carbon gas may have a lower decomposition temperature than the second carbon gas.

According to an embodiment, the first carbon gas may be an ethylene (C₂H₄) gas, an acetylene (C₂H₂) gas, a propane (C₃H₈) gas, a propylene (C₃H₆) gas, or a combination thereof, and the second carbon gas may be a methane (CH₄) gas.

The nitrogen-containing compound may be ammonia (NH₃), hydrazine (NH₂NH₂), pyridine (C₅H₅N), pyrrole (C₄H₅N), aniline (C₆H₅NH₂), acetonitrile (C₂H₃N), or a combination thereof.

One or more embodiments of the present disclosure provide a negative electrode for a rechargeable lithium battery, the negative electrode including a current collector and a negative active material layer disposed on the current collector and including the negative active material. The amount (content) of the silicon particles may be about 1 wt % to about 60 wt % based on the total weight (100 wt %) of the negative active material layer.

One or more embodiments of the present disclosure provide a rechargeable lithium battery including a negative electrode including the negative active material, a positive electrode including a positive active material, and an electrolyte.

The negative active material for a rechargeable lithium battery according to an embodiment may exhibit excellent or suitable charge rate and discharge rate characteristics.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic view showing a structure of the negative active material for a rechargeable lithium battery according to an embodiment.

FIG. 2 is a schematic view showing the structure of a rechargeable lithium battery according to an embodiment.

FIG. 3A is a 10-fold magnification SEM image of the negative active material prepared according to Example 1.

FIG. 3B is a 30-fold magnification SEM image of the negative active material prepared according to Example 1.

FIG. 3C is a 50-fold magnification SEM image of the negative active material prepared according to Example 1.

FIG. 4 is a graph showing cycle-life characteristics of rechargeable lithium battery cells including negative active materials prepared according to Example 1 and Comparative Examples 1 to 3.

### DETAILED DESCRIPTION

Hereinafter, embodiments of the present disclosure will be described in more detail. However, these embodiments are examples, the present disclosure is not limited thereto, and the present disclosure is defined by the scope of claims.

As used herein, the singular forms “a,” “an,” and “the” are intended to include the plural forms as well, unless the context clearly indicates otherwise. It will be further understood that the terms “includes,” “including,” “comprises,” and/or “comprising,” when used in this specification, specify the presence of stated features, steps, operations, elements, and/or components, but do not preclude the presence or addition of one or more other features, steps, operations, elements, components, and/or groups thereof.

As used herein, the terms “use,” “using,” and “used” may be considered synonymous with the terms “utilize,” “utilizing,” and “utilized,” respectively. Expressions such as “at least one of,” “one of,” and “selected from,” when preceding a list of elements, modify the entire list of elements and do not modify the individual elements of the list. The term “and/or” includes any and all combinations of one or more of the associated listed items. Further, the use of “may” when describing embodiments of the present disclosure refers to “one or more embodiments of the present disclosure”.

A negative active material for a rechargeable lithium battery according to an embodiment includes an amorphous carbon matrix; silicon particles dispersed in the amorphous carbon matrix; and a nitrogen-containing carbon compound disposed in a form protruding outward on the surface of the amorphous carbon matrix (e.g., a nitrogen-containing carbon compound protruding outward from the surface of the amorphous carbon matrix).

The nitrogen-containing carbon compound may have an urchin-like shape or structure. For example, the urchin-like structure may have the form or appearance of a plurality of needle-shaped or plate-shaped structures protruding outward from a central spheroidal mass.

The nitrogen-containing carbon compound may be semi-crystalline.

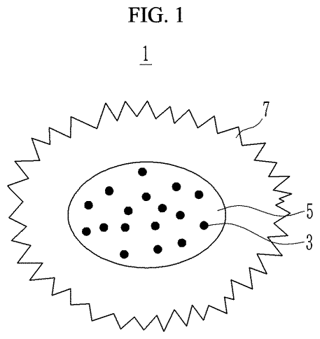

A schematic structure of the negative active material is shown in FIG. 1. As shown in FIG. 1, the negative active material 1 includes an amorphous carbon matrix 5, Si particles 3 dispersed in the amorphous carbon matrix 5, and a nitrogen-containing carbon compound 7 disposed in a form protruding outward on the surface of the amorphous carbon matrix.

As described above, the nitrogen-containing carbon compound 7 may be disposed unevenly in a form protruding outward from the surface of the amorphous carbon matrix 5 (e.g., structures of the nitrogen-containing carbon compound 7 having varying lengths protrude from the surface of the amorphous carbon matrix 5), that is, in an urchin-like structure.

This negative active material according to an embodiment includes very high-capacity silicon having a theoretical capacity of about 4200 mAh/g, and may thus provide a high-capacity battery; in addition, because the silicon particles are dispersed in the amorphous carbon matrix, volumetric expansion of the silicon particles may be effectively suppressed or reduced during the charge and discharge, and thus cycle-life characteristics may be improved. In comparison, when the silicon particles are dispersed in a crystalline carbon matrix rather than in the amorphous carbon matrix, the effect of suppressing the volume expansion of silicon may be insignificant or reduced, because crystalline carbon has higher hardness but lower toughness than amorphous carbon.

In the negative active material according to an embodiment, semi-crystalline carbon having excellent or suitable electrical conductivity is disposed on the surface of the negative active material to improve efficiency and/or charge and discharge rates. For example, because the nitrogen-containing carbon compound is semi-crystalline carbon, the electrical conductivity may be further improved.

When nitrogen is directly added to the amorphous carbon matrix, Si and the nitrogen added to the amorphous carbon come into direct contact, and may thus form silicon nitride (Si₃N₄) and silicon oxynitride (SiOₓN_{y}). When such product compounds (such as silicon nitride, silicon oxynitride, and/or the like) are present in the amorphous carbon matrix, battery capacity and efficiency may be deteriorated because these compounds are inert to and do not react with lithium (e.g., do not intercalate or dope with lithium ions).

The amorphous carbon may be soft carbon, hard carbon, or a combination thereof.

The nitrogen-containing carbon compound may be semi-crystalline. For example, the nitrogen-containing carbon compound has higher crystallinity than amorphous carbon but lower crystallinity than crystalline carbon, and thus may be graphite-like crystalline (e.g., have a crystallinity similar to graphite). The carbon compound on the surface of the amorphous carbon matrix outside the active material may be semi-crystalline, that is, carbon having different crystallinity from that of amorphous carbon, and may thus accomplish an effect of improving electrical conductivity, while the carbon in contact with the silicon particles may be amorphous carbon, and may thus effectively suppress or reduce volume expansion of the silicon particles during charging and discharging.

The nitrogen-containing carbon compound may include piperideine (C₅H₉N), piperidine (C₅H₁₁N), pyridine (C₅H₅N), pyrrole (C₄H₅N), aniline (C₆H₅NH₂), acetonitrile (C₂H₃N), dopamine (C₈H₁₁NO₂), dimethylamine, trimethylamine, ethylamine, diethylamine, trimethylamine, or a combination thereof.

In an embodiment, the weight ratio of the amorphous carbon matrix and the nitrogen-containing carbon compound may be about 1:1 to about 1:2. When the weight ratio of the amorphous carbon matrix and the nitrogen-containing carbon compound falls within this range, there may be an advantage in expansion characteristics during the cycle-life. When the weight ratio of the amorphous carbon matrix and the nitrogen-containing carbon compound is out of the range, for example, when the weight of the nitrogen-containing compound is more than twice (e.g., in amount) that of the amorphous carbon matrix, pores inside the amorphous carbon matrix may be rapidly formed, and an electrolyte solution may penetrate into the pores to deteriorate the silicon particles.

In the negative active material, an amount of the silicon particles may be about 40 wt % to about 80 wt % based on the total weight of the negative active material. When the amount of the silicon particles are within this range, excellent or suitable discharge capacity and improved capacity retention may be obtained.

In the negative active material, the silicon particles may be at least partially present as a silicon cluster formed by agglomeration of a plurality of the silicon particles. When present as the silicon cluster, the silicon cluster may have a size of about 4 μm to about 6 μm. When the silicon cluster has a size within this range, excellent or suitable initial expansion may be obtained.

A particle diameter of the silicon particles may be about 40 nm to about 250 nm, and according to an embodiment, about 80 nm to about 120 nm. This particle diameter may refer to an average particle diameter. The average particle diameter may be obtained by putting a plurality of particles into a particle size analyzer and measuring it, and may correspond to a particle diameter (D50) at a cumulative volume of 50 volume % in a cumulative size-distribution curve. For example, the particle diameter (D50), unless otherwise defined in the present specification, is an average particle diameter (D50) at a volume of 50 volume % in the cumulative particle size distribution.

The average particle diameter (D50) may be measured utilizing any suitable method in the art, for example, by utilizing a particle size analyzer, a transmission electron microscope (TEM), or a scanning electron microscope (SEM). In some embodiments, the average particle diameter (D50) may be obtained by measuring particle sizes with a device utilizing dynamic light-scattering, performing a data analysis, and counting the number of particles in each particle size range.

The negative active material according to an embodiment may be prepared by the following process.

A first carbon gas is injected into the silicon particles to prepare an amorphous carbon matrix in which the silicon particles are dispersed, and then the amorphous carbon matrix is subjected to a deposition process utilizing a second carbon gas and a gas of a nitrogen-containing compound, to form a nitrogen-containing carbon compound disposed to protrude to the outside on the surface of the amorphous carbon matrix, thus preparing a negative active material.

The silicon particles may have a particle diameter of about 40 nm to about 250 nm, and according to an embodiment, a particle diameter of about 80 nm to about 120 nm. The silicon particles may be utilized as a silicon cluster formed by agglomeration of a plurality of the silicon particles. This silicon cluster may be prepared in a spray-drying process.

The first carbon gas may have a lower decomposition temperature than the second carbon gas, and when a carbon gas having a low decomposition temperature is utilized, amorphous carbon may be formed. The first carbon gas may include, for example, ethylene (C₂H₄) gas, acetylene (C₂H₂) gas, propane (C₃H₈) gas, propylene (C₃H₆) gas, or a combination thereof.

The first carbon gas may be injected at about 600° C. to about 800° C. When the first carbon gas according to this injection process is decomposed, the amorphous carbon matrix is formed, and the silicon particles are dispersed in the amorphous carbon matrix. When this first carbon gas injection process is performed within this temperature range, a suitable amorphous carbon matrix may be more effectively obtained. When the first carbon gas injection process is performed at a temperature of less than about 600° C., it does not reach a decomposition temperature of carbon (e.g., carbon may not be decomposed) and thus carbon may not be deposited, and when the first carbon gas injection process is performed at a temperature of greater than about 800° C., the carbon may be deposited at the same rate but crystallinity of Si may be inappropriately or unsuitably increased.

In some embodiments, the process of forming the amorphous carbon matrix in which the silicon particles are dispersed may be performed by utilizing a chemical vapor deposition (CVD) process of injecting the first carbon gas into the silicon particles, or for example a carbonization or electro-spinning process of an organic compound under an inert gas atmosphere, but is not limited thereto.

The second carbon gas may be methane (CH₄) gas. The methane gas may be methane gas with a purity of 100%, or commercially available methane gas with a purity of 99% or higher.

The deposition process utilizing the second carbon gas and the gas of the nitrogen-containing compound may be a chemical vapor deposition (CVD) process. The deposition process may be performed at a temperature of greater than or equal to about 1000° C., or for example within a temperature range of about 1000° C. to about 1100° C.

According to the deposition process, the second carbon gas may be decomposed to produce semi-crystalline carbon, while the gas of the nitrogen-containing compound (that is, the nitrogen-containing compound in a gaseous form) is also decomposed to produce nitrogen, and this nitrogen is added (e.g., doped) into the semi-crystalline carbon, so that a nitrogen-containing carbon compound is grown on the surface of the amorphous carbon matrix, for example, in an urchin-like structure protruding outward from the surface of the amorphous carbon matrix.

When this nitrogen-containing compound is utilized in a liquid form rather than the gaseous form, the nitrogen-containing carbon compound may be formed in a smooth layered form or structure rather than the protruding urchin-like form, which may deteriorate the capacity, efficiency, rate capability, and/or cycle-life characteristics of the battery.

As described above, because the second carbon gas is utilized together with the gas of the nitrogen-containing compound during the deposition process, the nitrogen-containing carbon compound may be formed to protrude outward on the surface of the amorphous carbon matrix through one (e.g. a single) process, for example without separately performing a process of forming the urchin-like structure from the semi-crystalline carbon and then performing a process of adding the nitrogen.

In the deposition process, the second carbon gas and the gas of the nitrogen-containing compound may be mixed in a volume ratio of about 4:3 to about 6:1. When the second carbon gas and the gas of the nitrogen-containing compound are mixed within this range, an appropriate or suitable nitrogen-containing carbon compound may be prepared.

The nitrogen-containing compound may be ammonia (NH₃), hydrazine (NH₂NH₂), pyridine (C₅H₅N), pyrrole (C₄H₅N), aniline (C₆H₅NH₂), acetonitrile (C₂H₃N), or a combination thereof.

Another embodiment of the present disclosure provides a negative electrode for a rechargeable lithium battery including a current collector and a negative active material layer formed on this current collector and including the negative active material.

In the negative active material layer, the negative active material may be included in an amount of about 95 wt % to about 99 wt % based on the total weight of the negative active material layer.

The negative active material layer may include a binder, and may further optionally include a conductive material. In the negative active material layer, the binder may be included in an amount of about 1 wt % to about 5 wt % based on the total weight of the negative active material layer. In some embodiments, when a conductive material is further included, the negative active material may be utilized (included) in an amount of about 90 wt % to about 98 wt %, the binder may be utilized (included) in an amount of about 1 wt % to about 5 wt %, and the conductive material may be utilized (included) in an amount of about 1 wt % to about 5 wt %.

Herein, the negative active material layer includes the amorphous carbon matrix, the silicon particles dispersed in the amorphous carbon matrix, and the nitrogen-containing carbon compound disposed in a form protruding outward on the surface of the amorphous carbon matrix, and herein, the silicon particles may be included in an amount of about 1 wt % to about 60 wt % based on the total weight of the negative active material layer.

The binder may improve the binding properties of the negative active material particles with one another and with a current collector. The binder may be or include a non-aqueous binder, an aqueous binder, or a combination thereof.

The non-aqueous binder may include an ethylene-propylene copolymer, polyacrylonitrile, polystyrene, polyvinylchloride, carboxylated polyvinylchloride, polyvinylfluoride, polyurethane, polytetrafluoroethylene, polyvinylidene fluoride, polyethylene, polypropylene, polyamideimide, polyimide, or a combination thereof.

The aqueous binder may include a styrene-butadiene rubber, an acrylated styrene-butadiene rubber (ABR), an acrylonitrile-butadiene rubber, an acrylic rubber, a butyl rubber, a fluorine rubber, an ethylene oxide-containing polymer, polyvinylpyrrolidone, polyepichlorohydrin, polyphosphazene, an ethylene-propylene diene copolymer, polyvinylpyridine, chlorosulfonated polyethylene, latex, a polyester resin, an acrylic resin, a phenolic resin, an epoxy resin, polyvinyl alcohol, or any combination thereof.

When the aqueous binder is utilized as the negative electrode binder, a cellulose-based compound may be further utilized to provide viscosity as a thickener. The cellulose-based compound may include one or more of carboxymethyl cellulose, hydroxypropylmethyl cellulose, methyl cellulose, or an alkali metal salt of any thereof. The alkali metal may be sodium (Na), potassium (K), or lithium (Li). Such a thickener may be included in an amount of about 0.1 parts by weight to about 3 parts by weight based on 100 parts by weight of the negative active material.

The conductive material is included to provide electrode conductivity. Any electrically conductive material may be utilized as a conductive material unless it causes an unwanted chemical change (e.g., chemical reaction). Examples of the conductive material may include a carbon-based material (such as natural graphite, artificial graphite, carbon black, acetylene black, ketjen black, a carbon fiber, and/or the like); a metal-based material of a metal powder and/or a metal fiber including copper, nickel, aluminum, silver, and/or the like; a conductive polymer (such as a polyphenylene derivative); or a mixture thereof.

The current collector may include one selected from a copper foil, a nickel foil, a stainless steel foil, a titanium foil, a nickel foam, a copper foam, a polymer substrate coated with a conductive metal, and combinations thereof.

Another embodiment provides a rechargeable lithium battery including the negative electrode, a positive electrode including a positive active material, and an electrolyte between the negative electrode and the positive electrode. The positive electrode may include a positive current collector and a positive active material layer on the positive current collector. The positive active material may include lithiated intercalation compounds that reversibly intercalate and deintercalate lithium ions. For example, the positive active material may include one or more composite oxides of a metal selected from cobalt, manganese, nickel, and combinations thereof, and lithium. For example, the positive active material may be compounds represented by one of the following chemical formulae. LiₐA_{1-b}X_{b}D₂ (0.90≤a≤1.8, 0≤b≤0.5); LiₐA_{1-b}X_{b}O_{2-c}D_{c} (0.90≤a≤1.8, 0≤b≤0.5, 0≤c≤0.05); LiₐE_{1-b}X_{b}O_{2-c}D_{c} (0.90≤a≤1.8, 0≤b≤0.5, 0≤c≤0.05); LiₐE_{2-b}X_{b}O_{4-c}D_{c} (0.90≤a≤1.8, 0≤b≤0.5, 0≤c≤0.05); LiₐNi_{1-b-c}Co_{b}X_{c}D_{α} (0.90≤a≤1.8, 0≤b≤0.5, 0≤c≤0.5, 0<α≤2); LiₐNi_{1-b-c}Co_{b}X_{c}O_{2-α}T_{α} (0.90≤a≤1.8, 0≤b≤0.5, 0≤c≤0.5, 0<α<2); LiₐNi_{1-b-c}Co_{b}X_{c}O_{2-α}T₂ (0.90≤a≤1.8, 0≤b≤0.5, 0≤c≤0.05, 0<α<2); LiₐNi_{1-b-c}Mn_{b}X_{c}D_{α} (0.90≤a≤1.8, 0≤b≤0.5, 0≤c≤0.05, 0<α≤2); LiₐNi_{1-b-c}Mn_{b}X_{c}O_{2-α}T_{α} (0.90≤a≤1.8, 0≤b≤0.5, 0≤c≤0.5, 0<α<2); LiₐNi_{1-b-c}Mn_{b}X_{c}O_{2-α}T₂ (0.90≤a≤1.8, 0≤b≤0.5, 0≤c≤0.5, 0<α<2); LiₐNi_{b}E_{c}G_{d}O₂ (0.90≤a≤1.8, 0≤b≤0.9, 0≤c≤0.5, 0.001≤d≤0.1); LiₐNi_{b}Co_{c}Mn_{d}GₑO₂ (0.90≤a≤1.8, 0≤b≤0.9, 0≤c≤0.5, 0≤d≤0.5, 0.001≤e≤0.1); LiₐNiG_{b}O₂ (0.90≤a≤1.8, 0.001≤b≤0.1) LiₐCoG_{b}O₂ (0.90≤a≤1.8, 0.001≤b≤0.1); LiₐMn_{1-b}GbO₂ (0.90≤a≤1.8, 0.001≤b≤0.1); LiₐMn₂G_{b}O₄ (0.90≤a≤1.8, 0.001≤b≤0.1); LiₐMn_{1-g}G_{g}PO₄ (0.90≤a≤1.8, 0≤g≤0.5); QO₂; QS₂; LiQS₂; V₂O₅; LiV₂O₅; LiZO₂; LiNiVO₄; Li_{(3-f)}J₂(PO₄)₃ (0≤f≤2); Li_{(3-f)}Fe₂(PO₄)₃ (0≤f≤2); LiₐFePO₄ (0.90≤a≤1.8)

In the chemical formulas, A is selected from nickel (Ni), cobalt (Co), manganese (Mn), and a combination thereof; X is selected from aluminum (Al), Ni, Co, Mn, chromium (Cr), iron (Fe), magnesium (Mg), strontium (Sr), vanadium (V), a rare earth element, and a combination thereof; D is selected from oxygen (O), fluorine (F), sulfur (S), phosphorus (P), and a combination thereof; E is selected from Co, Mn, and a combination thereof; T is selected from F, S, P, and a combination thereof; G is selected from Al, Cr, Mn, Fe, Mg, lanthanum (La), cerium (Ce), Sr, V, and a combination thereof; Q is selected from titanium (Ti), molybdenum (Mo), Mn, and a combination thereof; Z is selected from Cr, V, Fe, scandium (Sc), yttrium (Y), and a combination thereof; and J is selected from V, Cr, Mn, Co, Ni, copper (Cu), and a combination thereof.

The compounds may have a coating layer on the surface, or may be mixed with another compound having a coating layer. The coating layer may include at least one coating element compound selected from an oxide of a coating element, a hydroxide of a coating element, an oxyhydroxide of a coating element, an oxycarbonate of a coating element, and a hydroxyl carbonate of a coating element. The compound for the coating layer may be amorphous or crystalline. The coating element included in the coating layer may include Mg, Al, Co, K, Na, calcium (Ca), Si, Ti, V, Sn, germanium (Ge), gallium (Ga), boron (B), arsenic (As), zirconium (Zr), or a mixture thereof. The coating layer may be disposed (applied) utilizing any suitable method that does not have an adverse influence on the properties of a positive active material caused by the elements in the compound. For example, the method may include any suitable coating method (such as spray coating, dipping, and/or the like), which are not illustrated in more detail because they are well-known in the related art.

In the positive electrode, a content of the positive active material may be about 90 wt % to about 98 wt % based on the total weight of the positive active material layer.

In an embodiment, the positive active material layer may further include a binder and a conductive material. Herein, each amount of the binder and the conductive material may be about 1 wt % to about 5 wt % based on the total weight of the positive active material layer.

The binder may improve the binding properties of positive active material particles with one another and with a current collector. Examples of the binder may include polyvinyl alcohol, carboxymethyl cellulose, hydroxypropyl cellulose, diacetyl cellulose, polyvinylchloride, carboxylated polyvinylchloride, polyvinylfluoride, an ethylene oxide-containing polymer, polyvinylpyrrolidone, polyurethane, polytetrafluoroethylene, polyvinylidene fluoride, polyethylene, polypropylene, styrene-butadiene rubber, acrylated styrene-butadiene rubber, an epoxy resin, nylon, and/or the like, but are not limited thereto.

The conductive material is included to provide electrode conductivity. Any electrically conductive material may be utilized as a conductive material unless it causes an unwanted chemical change. Examples of the conductive material may include a carbon-based material (such as natural graphite, artificial graphite, carbon black, acetylene black, ketjen black, a carbon fiber and/or the like); a metal-based material of a metal powder or a metal fiber including copper, nickel, aluminum, silver, and/or the like; a conductive polymer (such as a polyphenylene derivative); or a mixture thereof.

The current collector may include Al, but is not limited thereto.

The electrolyte includes a non-aqueous organic solvent and a lithium salt.

The non-aqueous organic solvent serves as a medium for transmitting ions taking part in the electrochemical reaction of a battery.

The non-aqueous organic solvent may include a carbonate-based, ester-based, ether-based, ketone-based, alcohol-based, or aprotic solvent.

The carbonate based solvent may include dimethyl carbonate (DMC), diethyl carbonate (DEC), dipropyl carbonate (DPC), methylpropyl carbonate (MPC), ethylpropyl carbonate (EPC), methylethyl carbonate (MEC), ethylene carbonate (EC), propylene carbonate (PC), butylene carbonate (BC), and/or the like. The ester-based solvent may include methyl acetate, ethyl acetate, n-propyl acetate, t-butyl acetate, dimethylacetate, methylpropionate, ethylpropionate, decanolide, mevalonolactone, caprolactone, and/or the like. The ether-based solvent may include dibutyl ether, tetraglyme, diglyme, dimethoxyethane, 2-methyltetrahydrofuran, tetrahydrofuran, and/or the like. The ketone-based solvent includes cyclohexanone and/or the like. The alcohol-based solvent includes ethyl alcohol, isopropyl alcohol, and/or the like, and examples of the aprotic solvent may include nitriles such as R—CN (where R is a C₂ to C₂₀ linear, branched, or cyclic hydrocarbon group, an aromatic ring including a double bond, or an ether bond), amides (such as dimethylformamide), dioxolanes (such as 1,3-dioxolane), sulfolanes, and/or the like.

The organic solvent may be utilized alone or in a mixture. When the organic solvent is utilized in a mixture, the mixture ratio may be controlled or selected in accordance with the desired or suitable battery performance.

In some embodiments, the carbonate-based solvent may be a mixture of cyclic carbonate and chain carbonate. In this case, when the cyclic carbonate and the chain carbonate are mixed in a volume ratio of about 1:1 to about 1:9, the electrolyte may exhibit excellent or suitable performance.

The organic solvent may further include an aromatic hydrocarbon-based organic solvent in addition to the carbonate-based solvent. Herein, the carbonate-based solvent and the aromatic hydrocarbon-based organic solvent may be mixed in a volume ratio of about 1:1 to about 30:1.

The aromatic hydrocarbon-based organic solvent may be an aromatic hydrocarbon-based compound of Chemical Formula 1.

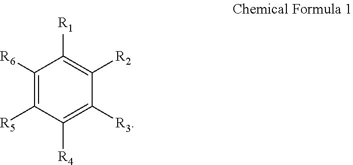

In Chemical Formula 1, R₁ to R₆ may each independently be the same or different and may be selected from hydrogen, a halogen, a C₁ to C₁₀ alkyl group, a haloalkyl group, and a combination thereof.

Examples of the aromatic hydrocarbon-based organic solvent may include benzene, fluorobenzene, 1,2-difluorobenzene, 1,3-difluorobenzene, 1,4-difluorobenzene, 1,2,3-trifluorobenzene, 1,2,4-trifluorobenzene, chlorobenzene, 1,2-dichlorobenzene, 1,3-dichlorobenzene, 1,4-dichlorobenzene, 1,2,3-trichlorobenzene, 1,2,4-trichlorobenzene, iodobenzene, 1,2-diiodobenzene, 1,3-diiodobenzene, 1,4-diiodobenzene, 1,2,3-triiodobenzene, 1,2,4-triiodobenzene, toluene, fluorotoluene, 2,3-difluorotoluene, 2,4-difluorotoluene, 2,5-difluorotoluene, 2,3,4-trifluorotoluene, 2,3,5-trifluorotoluene, chlorotoluene, 2,3-dichlorotoluene, 2,4-dichlorotoluene, 2,5-dichlorotoluene, 2,3,4-trichlorotoluene, 2,3,5-trichlorotoluene, iodotoluene, 2,3-diiodotoluene, 2,4-diiodotoluene, 2,5-diiodotoluene, 2,3,4-triiodotoluene, 2,3,5-triiodotoluene, xylene, and/or combinations thereof.

The electrolyte may further include an additive of vinylene carbonate and/or an ethylene carbonate-based compound of Chemical Formula 2 in order to improve a cycle-life of a battery:

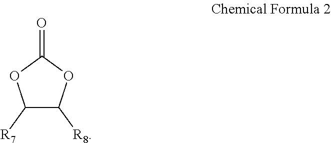

In Chemical Formula 2, R₇ and R₈ may each independently be the same or different and may be selected from hydrogen, a halogen, a cyano group (CN), a nitro group (NO₂), and a fluorinated C₁ to C₅ alkyl group, provided that at least one of R₇ and R₈ is selected from a halogen, a cyano group (CN), a nitro group (NO₂), and a fluorinated C₁ to C₅ alkyl group, and R₇ and R₈ are not concurrently (e.g., simultaneously) hydrogen.

Examples of the ethylene carbonate-based compound may include difluoro ethylene carbonate, chloroethylene carbonate, dichloroethylene carbonate, bromoethylene carbonate, dibromoethylene carbonate, nitroethylene carbonate, cyanoethylene carbonate, and/or fluoroethylene carbonate. The amount of the additive for improving a cycle-life may be utilized within an appropriate or suitable range.

The lithium salt dissolved in an organic solvent supplies a battery with lithium ions, basically operates the rechargeable lithium battery, and improves transportation of the lithium ions between positive and negative electrodes. Examples of the lithium salt may include at least one supporting salt selected from LiPF₆, LiBF₄, LiSbF₆, LiAsF₆, LiN(SO₂C₂F₅)₂, Li(CF₃SO₂)₂N, LiN(SO₃C₂F₅)₂, Li(FSO₂)₂N (lithium bis(fluorosulfonyl)imide: LiFSI), LiC₄F₉SO₃, LiClO₄, LiAlO₂, LiAlCl₄, LiN(CₓF₂ₓ₊₁SO₂)(C_{y}F_{2y+1}O₂) (where x and y are natural numbers, for example an integer of 1 to 20), LiCl, LiI, and LiB(C₂O₄)₂ (lithium bis(oxalato) borate: LiBOB). A concentration of the lithium salt may range from about 0.1 M to about 2.0 M. When the lithium salt is included at the above concentration range, an electrolyte may have excellent or suitable performance and lithium ion mobility due to optimal or suitable electrolyte conductivity and viscosity.

The rechargeable lithium battery may further include a separator between the negative electrode and the positive electrode, depending on the type or format of the battery. Examples of a suitable separator material may include polyethylene, polypropylene, polyvinylidene fluoride, and multi-layers thereof such as a polyethylene/polypropylene double-layered separator, a polyethylene/polypropylene/polyethylene triple-layered separator, and a polypropylene/polyethylene/polypropylene triple-layered separator.

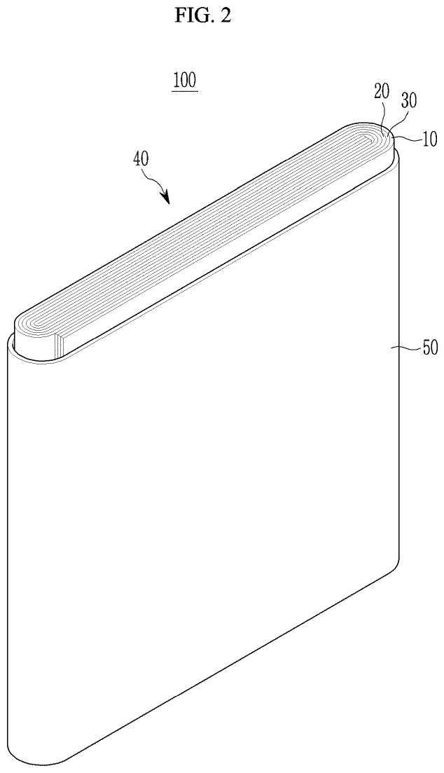

FIG. 2 is an exploded perspective view of a rechargeable lithium battery according to one embodiment. The rechargeable lithium battery according to an embodiment is illustrated as a prismatic battery but is not limited thereto and may include variously-shaped batteries (such as a cylindrical battery, a pouch battery, and/or the like).

Referring to FIG. 2, a rechargeable lithium battery 100 according to an embodiment includes an electrode assembly 40 manufactured by winding a separator 30 interposed between a positive electrode 10 and a negative electrode 20, and a case 50 housing the electrode assembly 40. An electrolyte may be impregnated in the positive electrode 10, the negative electrode 20, and the separator 30.

Hereinafter, examples of the present disclosure and comparative examples are described. These examples, however, are not in any sense to be interpreted as limiting the scope of the present disclosure.

### Example 1

Silicon particles were pulverized to prepare silicon particles having an average particle diameter (D50) of 100 nm.

The obtained silicon particles having an average particle diameter (D50) of 100 nm were spray-dried to prepare silicon clusters having an average particle diameter (D50) of 5 μm.

Subsequently, ethylene (C₂H₂) gas was injected into the silicon clusters to perform chemical vapor deposition (CVD) at 800° C. Through this process, an amorphous carbon matrix was formed, and the silicon clusters were dispersed throughout the amorphous carbon matrix.

Subsequently, while methane (CH₄) gas and NH₃ gas in a volume ratio of 4:3 were injected into the amorphous carbon matrix, the chemical vapor deposition (CVD) was performed at 1000° C. Through this process, on the surface of the amorphous carbon matrix, a piperideine compound that is a semi-crystalline nitrogen-containing carbon compound was grown, preparing a negative active material for a rechargeable lithium battery including the nitrogen-containing carbon compound in an urchin-like structure protruding outward on the surface of the amorphous carbon matrix.

In the prepared negative active material, an amount of the silicon particles was 55 wt % based on the total weight of the negative active material, an amount of the amorphous carbon was 20 wt % based on the total weight of the negative active material, and an amount of the semi-crystalline nitrogen containing-carbon compound was 25 wt % based on the total weight of the negative active material.

97.5 wt % of the negative active material, 1.0 wt % of carboxymethyl cellulose, and 1.5 wt % of styrene-butadiene rubber were mixed in distilled water to prepare a negative active material slurry composition.

The negative active material slurry composition was coated on a Cu current collector, and then dried and compressed to manufacture a negative electrode for a rechargeable lithium battery.

The negative electrode, a lithium metal counter electrode, and an electrolyte solution were utilized to fabricate a half-cell. The electrolyte solution was prepared by utilizing a mixed solvent of ethylene carbonate and dimethyl carbonate (a volume ratio of 3:7) and dissolving 1 M LiPF₆ therein.

### Comparative Example 1

The silicon clusters according to Example 1 and petroleum pitch were mixed in a weight ratio of 46:54, and heat-treated at 950° C. to prepare a negative active material for a rechargeable lithium battery in which the silicon clusters were dispersed in a soft carbon amorphous carbon matrix.

The negative active material was utilized according to substantially the same method as Example 1 to manufacture a negative electrode and a half-cell.

### Comparative Example 2

Silicon particles were pulverized to prepare silicon particles having an average particle diameter (D50) of 100 nm.

The obtained silicon particles having an average particle diameter (D50) of 100 nm were spray-dried to prepare silicon clusters having an average particle diameter (D50) of 5 μm.

Subsequently, ethylene (C₂H₂) gas was injected into the silicon clusters to perform chemical vapor deposition (CVD) at 800° C. Through this process, an amorphous carbon matrix was formed, and the silicon clusters were dispersed throughout the amorphous carbon matrix.

Subsequently, while methane (CH₄) gas was injected into the amorphous carbon matrix, chemical vapor deposition (CVD) was performed at 1000° C. Through this process, on the surface of the amorphous carbon matrix, semi-crystalline carbon was grown, preparing a negative active material for a rechargeable lithium battery including the semi-crystalline carbon in an urchin-like structure protruding outward on the surface of the amorphous carbon matrix.

In the prepared negative active material, an amount of the silicon particles was 55 wt % based on the total weight of the negative active material, an amount of the amorphous carbon was 20 wt % based on the total weight of the negative active material, and an amount of the semi-crystalline carbon was 25 wt % based on the total weight of the negative active material.

The negative active material was utilized according to substantially the same method as Example 1 to manufacture a negative electrode and a half-cell.

### Comparative Example 3

0.6 g of the silicon clusters according to Example 1 and 1.4 g of an 1-ethyl-3-methylimidazolium dicyanamide ionic liquid were well mixed and well stirred. The mixture was heat-treated under nitrogen gas at 300° C. for 1 hour, and then carbonized at 1000° C. for 1 hour, thus preparing a negative active material for a rechargeable lithium battery in which nitrogen-doped carbon was coated on SiO₂.

The negative active material was utilized according to substantially the same method as Example 1 to manufacture a negative electrode and a half-cell.

SEM Photograph

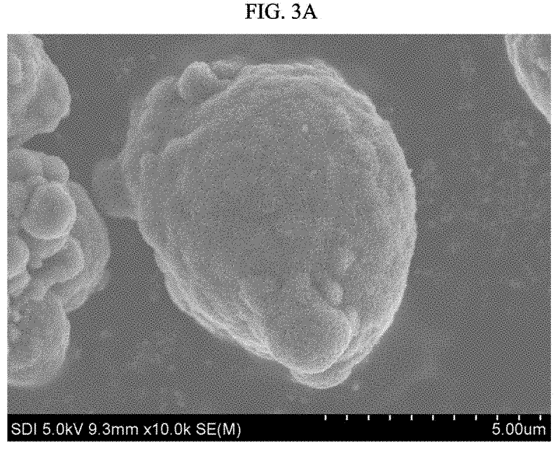

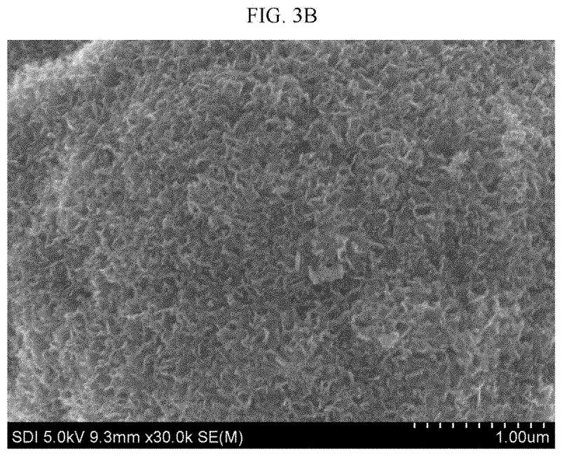

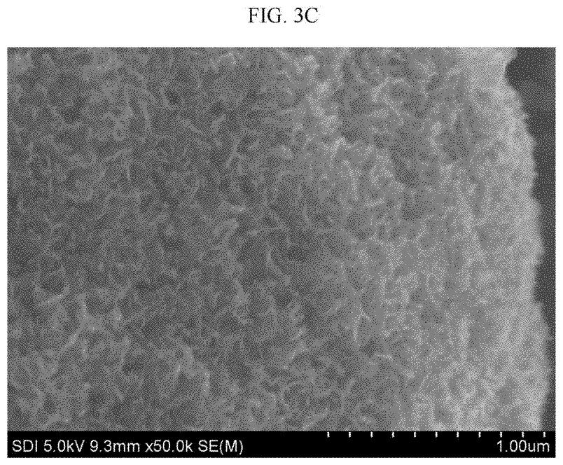

FIG. 3A shows a 10× magnification SEM image of the negative active material according to Example 1, FIG. 3B shows a 30× magnification SEM image thereof, and FIG. 3C shows a 50× magnification SEM image thereof. As shown in FIGS. 3A, 3B, and 3C, the negative active material of Example 1 had an uneven surface as in an urchin-like structure, in which the nitrogen-containing carbon compound was observed to be in the urchin-like structure protruding outward on the surface.

Evaluation of Formation Charge/Discharge Characteristics

The half-cells according to Example 1 and Comparative Examples 1 to 3 were once charged and discharged at 1 C to measure the charge capacity and discharge capacity. The efficiency (a percentage of discharge capacity/charge capacity) of the cells was calculated as discharge capacity relative to the measured charge capacity, and the results are provided as formation efficiency (first row) in Table 1. The measured discharge capacity is shown as a standard discharge (second row) in Table 1.

Evaluation of High-Rate Characteristics

The half-cells according to Example 1 and Comparative Examples 1 to 3 were each once charged and discharged at 0.2 C and then, once charged and discharged at 2 C to measure the charge capacity and discharge capacity. A ratio of the measured 2 C charge capacity related to the measured 0.2 C charge capacity was calculated, and the results of the evaluation (each shown as a charge rate) are shown in Table 1 (third row), and a ratio of the measured 2 C discharge capacity related to the measured 0.2 C discharge capacity was calculated, and the results of the evaluation (each shown as a discharge rate) are shown in Table 1 (fourth row).

TABLE 1

| | Example | Comparative | Comparative | Comparative |
|---|---|---|---|---|
| | 1 | Example 1 | Example 2 | Example 3 |
| Formation efficiency | 90.1 | 88.5 | 89.8 | 86.2 |
| (%) | | | | |
| Standard discharge | 506.5 | 504.1 | 503.6 | 498.2 |
| (mAh/g) | | | | |
| Charge rate | 42.0 | 41.8 | 40.3 | 34.8 |
| (2 C/0.2 C, %) | | | | |
| Discharge rate | 96.6 | 95.9 | 95.9 | 96.0 |
| (2 C/0.2 C, %) | | | | |

As shown in Table 1, the half-cell of Example 1 exhibited excellent or suitable formation efficiency and standard discharge characteristics, compared with the half-cells of Comparative Examples 1 to 3. In addition, the half-cell of Example 1 exhibited excellent or suitable charge rate and discharge rate, compared with the half-cells of Comparative Examples 1 to 3.

Evaluation of Cycle-Life Characteristics

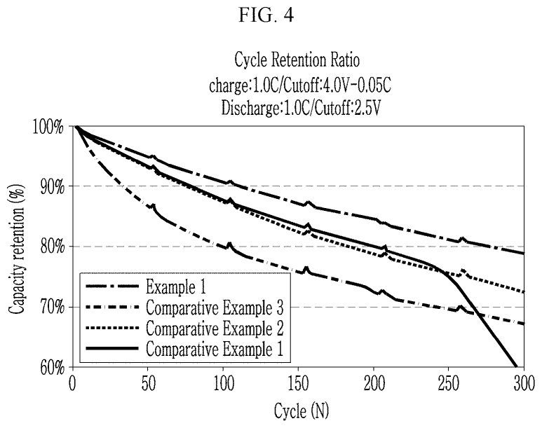

The half-cells of Example 1 and the Comparative Examples 1 to 3 were charged under conditions of 1.0 C and a 4.0 V-0.05 C cut-off, and discharged under conditions of 1.0 C and 2.5 V cut-off, which was repeated 300 times. When the 1^{st} discharge capacity was regarded as 100%, a capacity ratio at each cycle was calculated, and the capacity retention results are shown in FIG. 4.

As shown in FIG. 4, Example 1 exhibited excellent or suitable capacity retention at the 300^{th} charge and discharge, compared with Comparative Examples 1 to 3. Comparative Example 1 including silicon and amorphous carbon alone exhibited sharply decreased capacity retention after the 250^{th} charge and discharge, while Comparative Example 2 including semi-crystalline carbon in addition to the silicon and the amorphous carbon exhibited no sharply decreased capacity retention even after the 250^{th} charge and discharge but lower capacity retention compared to Example 1. Comparative Example 3 (to which nitrogen was added as a liquid) exhibited the lowest capacity retention.

Referring to these results, even though a carbon layer formed of crystalline carbon was included in the negative active material, when doped with nitrogen, particularly, doped with gaseous nitrogen, the capacity retention turned out to be more improved.

As used herein, the terms “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

While this disclosure has been described in connection with what is presently considered to be practical embodiments, it is to be understood that the present disclosure is not limited to the disclosed embodiments, but, on the contrary, is intended to cover various modifications and equivalent arrangements included within the spirit and scope of the appended claims.

What is claimed is:

1. A negative active material for a rechargeable lithium battery, the negative active material comprising:
an amorphous carbon matrix;
silicon particles dispersed in the amorphous carbon matrix; and
a nitrogen-containing carbon compound protruding outward from a surface of the amorphous carbon matrix.

2. The negative active material of claim 1, wherein the nitrogen-containing carbon compound has an urchin-like structure on the surface of the amorphous carbon matrix.

3. The negative active material of claim 1, wherein the nitrogen-containing carbon compound is semi-crystalline.

4. The negative active material of claim 1, wherein the nitrogen-containing carbon compound comprises piperideine (C₅H₉N), piperidine (C₅H₁₁N), pyridine (C₅H₅N), pyrrole (C₄H₅N), aniline (C₆H₅NH₂), acetonitrile (C₂H₃N), dopamine (C₈H₁₁NO₂), dimethylamine, trimethylamine, ethylamine, diethylamine, trimethylamine, or a combination thereof.

5. The negative active material of claim 1, wherein a weight ratio of the amorphous carbon matrix and the nitrogen-containing carbon compound is about 1:1 to about 1:2.

6. The negative active material of claim 1, wherein an amount of the silicon particles is about 40 wt % to about 80 wt % based on a total amount of the negative active material.

7. The negative active material of claim 1, wherein a particle diameter of the silicon particles is about 40 nm to about 250 nm.

8. A method of preparing a negative active material for a rechargeable lithium battery, the method comprising:
injecting a first carbon gas into silicon particles and performing heat treatment to prepare an amorphous carbon matrix in which the silicon particles are dispersed; and
performing a deposition process on the amorphous carbon matrix by utilizing a second carbon gas and a gas of a nitrogen-containing compound to form a nitrogen-containing carbon compound protruding outward from a surface of the amorphous carbon matrix.

9. The method of claim 8, wherein the injecting of the first carbon gas is performed at a temperature of about 600° C. to about 800° C.

10. The method of claim 8, wherein the deposition process is a chemical vapor deposition (CVD) process.

11. The method of claim 8, wherein the deposition process is performed at a temperature of greater than or equal to about 1000° C.

12. The method of claim 8, wherein the first carbon gas has a lower decomposition temperature than the second carbon gas.

13. The method of claim 11, wherein the first carbon gas is an ethylene (C₂H₄) gas, an acetylene (C₂H₂) gas, a propane (C₃H₈) gas, a propylene (C₃H₆) gas, or a combination thereof.

14. The method of claim 11, wherein the second carbon gas is a methane (CH₄) gas.

15. The method of claim 8, wherein the nitrogen-containing compound is ammonia (NH₃), hydrazine (NH₂NH₂), pyridine (C₅H₅N), pyrrole (C₄H₅N), aniline (C₆H₅NH₂), acetonitrile (C₂H₃N), or a combination thereof.

16. A negative electrode for a rechargeable lithium battery, the negative electrode comprising:
a current collector; and
a negative active material layer on the current collector and comprising the negative active material of claim 1.

17. The negative electrode of claim 16, wherein an amount of the silicon particles is about 1 wt % to about 60 wt % based on a total amount of the negative active material layer.

18. A rechargeable lithium battery, the rechargeable lithium battery comprising:
a negative electrode comprising the negative active material of claim 1;
a positive electrode comprising a positive active material; and
an electrolyte.
